(19) United States
(12) Patent Application Publication
(10) Pub. No.: US 2023/0097353 A1
(43) Pub. Date: Mar. 30, 2023

(54) WAFER, ELECTRONIC COMPONENT AND METHOD USING LINED AND CLOSED SEPARATION TRENCH

(71) Applicant: Infineon Technologies AG, Neubiberg (DE)

(72) Inventors: Oliver BLANK, Villach (AT); Tobias POLSTER, Finkenstein (AT); Sylvain LEOMANT, Pörtschach am Wörthersee (AT)

(73) Assignee: Infineon Technologies AG, Neubiberg (DE)

(21) Appl. No.: 17/946,471

(22) Filed: Sep. 16, 2022

(30) Foreign Application Priority Data
Sep. 29, 2021 (DE) 10 2021 125 239.3

(51) Int. Cl. H01L 21/78; H01L 21/762

(52) U.S. Cl. CPC H01L 21/78; H01L 21/76224; H01L 2221/68327

(57) ABSTRACT

A method of processing a wafer is disclosed. In one example, the method comprises providing the wafer with a separation frame separating neighboured electronic components, forming separation trenches in the separation frame and at least partially lining sidewalls of the separation trenches with a sidewall lining for partially filling the separation trenches while maintaining a void volume therein. An exterior opening of the separation trenches is closed by a closing structure.

### CROSS-REFERENCE TO RELATED APPLICATION

This Utility patent application claims priority to German Patent Application No. 10 2021 125 239.3, filed Sep. 29, 2021, which is incorporated herein by reference.

### BACKGROUND OF THE INVENTION

### Field of the Invention

The present invention relates to a wafer, an electronic component, and a method of processing a wafer.

### Description of the Related Art

Packages may be denoted as for example encapsulated electronic chips with electrical connects and being mounted to an electronic periphery, for instance on a printed circuit board. Before packaging, a semiconductor wafer is singularized into a plurality of electronic chips. After singularizing the wafer into the singularized electronic chips, the electronic chips of the wafer may be subsequently used for further processing.

Singularization may be accomplished by mechanically or laser cutting the wafer. However, separated electronic components may be damaged during separation. Moreover, the process of separating the electronic components from the wafer compound may be cumbersome.

### SUMMARY

There may be a need to separate electronic components from a wafer in an efficient way and with a low risk of damage.

According to an exemplary embodiment, a method of processing a wafer is provided, wherein the method comprises providing the wafer with a separation frame separating neighboured electronic components, forming separation trenches in the separation frame, at least partially lining sidewalls of the separation trenches with a sidewall lining for partially filling the separation trenches while maintaining a void volume therein, and closing an exterior opening of the separation trenches by a closing structure.

According to another exemplary embodiment, an electronic component is provided which comprises a semiconductor body, an active region in and/or on a central portion of the semiconductor body, and a sidewall lining covering at least part of a sidewall of the semiconductor body, wherein the sidewall lining comprises another material than the semiconductor body, and wherein an exterior surface of at least an upper portion of a sidewall of the electronic component is a breaking edge.

According to still another exemplary embodiment, a wafer is provided which comprises an array of a plurality of electronic components, a separation frame separating neighboured electronic components, separation trenches in the separation frame, a sidewall lining at least partially lining sidewalls of the separation trenches for partially filling the separation trenches while maintaining a void volume therein, and a closing structure closing an exterior opening of the separation trenches.

According to an exemplary embodiment, separation of a wafer into individual electronic components, which are previously integrally connected in the wafer compound and spaced by a separation frame, may be carried out with low effort and high reliability by integrating separation trenches in the separation frame prior to an actual separation process. Highly advantageously, sidewalls of such separation trenches may be at least partially coated with a sidewall lining for protecting the covered or passivated sidewall from contamination (for instance a metallic contamination and/or dirt) during further processing of the wafer. Advantageously, this may prevent an undesirable degradation of an electronic component. Furthermore, the separation trenches may be closed at an upper end prior to the actual separation process by a closing structure for protecting a remaining void volume of the trenches against contamination (for instance a metallic contamination and/or dirt) during processing of the wafer (in particular during front end of the line processing). Advantageously, the sidewall lining as well as the closing structure may only partially fill the respective separation trench for maintaining a void volume therein which functions to define or determine a predetermined breaking point during actual separation of the wafer into individual electronic components. As a result of a corresponding separation process, a breaking edge may remain at the singularized electronic components at least in an upper lateral surface region thereof. Advantageously, the described separation architecture may allow to render the time needed for separation independent of the dimension of an electronic component (for instance embodied as semiconductor chip) and allows a reliable and low effort separation in a fast and high quality fashion.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 shows a cross-sectional view of a wafer according to an exemplary embodiment.

FIG. 2 shows a cross-sectional view of an electronic component according to an exemplary embodiment.

FIG. 3 shows a flowchart of a method of processing a wafer according to an exemplary embodiment.

FIG. 4 to FIG. 11 show cross-sectional views of structures obtained during carrying out a method of separating a wafer into electronic components according to an exemplary embodiment.

FIG. 12 to FIG. 15 show plan views of wafers according to exemplary embodiments.

### DETAILED DESCRIPTION

There may be a need to separate electronic components from a wafer in an efficient way and with a low risk of damage.

According to an exemplary embodiment, a method of processing a wafer is provided, wherein the method comprises providing the wafer with a separation frame separating neighboured electronic components, forming separation trenches in the separation frame, at least partially lining sidewalls of the separation trenches with a sidewall lining for partially filling the separation trenches while maintaining a void volume therein, and closing an exterior opening of the separation trenches by a closing structure.

According to another exemplary embodiment, an electronic component is provided which comprises a semiconductor body, an active region in and/or on a central portion of the semiconductor body, and a sidewall lining covering at least part of a sidewall of the semiconductor body, wherein the sidewall lining comprises another material than the semiconductor body, and wherein an exterior surface of at least an upper portion of a sidewall of the electronic component is a breaking edge.

According to still another exemplary embodiment, a wafer is provided which comprises an array of a plurality of electronic components, a separation frame separating neighboured electronic components, separation trenches in the separation frame, a sidewall lining at least partially lining sidewalls of the separation trenches for partially filling the separation trenches while maintaining a void volume therein, and a closing structure closing an exterior opening of the separation trenches.

According to an exemplary embodiment, separation of a wafer into individual electronic components, which are previously integrally connected in the wafer compound and spaced by a separation frame, may be carried out with low effort and high reliability by integrating separation trenches in the separation frame prior to an actual separation process. Highly advantageously, sidewalls of such separation trenches may be at least partially coated with a sidewall lining for protecting the covered or passivated sidewall from contamination (for instance a metallic contamination and/or dirt) during further processing of the wafer. Advantageously, this may prevent an undesirable degradation of an electronic component. Furthermore, the separation trenches may be closed at an upper end prior to the actual separation process by a closing structure for protecting a remaining void volume of the trenches against contamination (for instance a metallic contamination and/or dirt) during processing of the wafer (in particular during front end of the line processing). Advantageously, the sidewall lining as well as the closing structure may only partially fill the respective separation trench for maintaining a void volume therein which functions to define or determine a predetermined breaking point during actual separation of the wafer into individual electronic components. As a result of a corresponding separation process, a breaking edge may remain at the singularized electronic components at least in an upper lateral surface region thereof. Advantageously, the described separation architecture may allow to render the time needed for separation independent of the dimension of an electronic component (for instance embodied as semiconductor chip) and allows a reliable and low effort separation in a fast and high quality fashion.

### DESCRIPTION OF FURTHER EXEMPLARY EMBODIMENTS

In the following, further exemplary embodiments of the wafer, the electronic component, and the method will be explained.

In the context of the present application, the term “wafer” may particularly denote a semiconductor substrate which has been processed to form a plurality of integrated circuit elements in an active region of electronic components of the wafer and which may be singularized into a plurality of separate electronic components or chips. For example, a wafer may have a disk shape and may comprise a matrix-like arrangement of electronic components in rows and columns. It is possible that a wafer has a circular geometry or a polygonal geometry (such as a rectangular geometry or a triangular geometry).

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a pressure sensor, a light sensor or a gas sensor), an actuator (for instance a loudspeaker), and a microelectromechanical system (MEMS, for instance a loudspeaker, a member comprising a mechanical spring, etc.). However, in other embodiments, the electronic component may also be of different type, such as a mechatronic member, in particular a mechanical switch, etc.

In the context of the present application, the term “separation frame” may particularly denote a physical structure of a wafer between adjacent integrally connected electronic components. For instance, such a separation frame may comprise straight sections running along rows and columns and being connected with each other in intersection or crossing regions.

In the context of the present application, the term “separation trench” may particularly denote a recess extending from one main surface, in particular from a front side, of a wafer into material, in particular semiconductor material, thereof. Such a trench may have an aspect ratio, i.e. a ratio between vertical depth and horizontal width, of larger than one, in particular larger than three, more particularly larger than five. In particular, a separation trench may be a circumferentially closed structure surrounding an entire electronic component to be separated from the wafer.

In the context of the present application, the term “sidewall lining” may particularly denote a partially or full coating of sidewalls of a separation trench with a material being distinguishable from adjacent material of the wafer or of the semiconductor body of the electronic components. Such a sidewall lining may have a homogeneous or an inhomogeneous thickness. The sidewall lining may also cover a bottom of a separation trench.

In the context of the present application, the term “void volume” may particularly denote a hollow region in an interior of a separation trench being defined or delimited by the sidewall lining and the closing structure, and optionally by semiconductor wafer material. Hence, the void volume may be free of solid material. For instance, the void volume may be shaped as a vertically elongated circumferential slit.

In the context of the present application, the term “closing structure” may particularly denote material closing an exterior opening of a separation trench to thereby delimit the void volume from an upper side. Thus, the closing structure may mechanically decouple the void volume with regard to an exterior of the wafer or the electronic component. The closing structure may be integrally formed with the sidewall lining, or may be a separate structure distinguishable from the sidewall lining.

In the context of the present application, the term “active region” may particularly denote a (for example surface-limited or fully volumetric) region of a semiconductor body of a wafer or an electronic component, in and/or on which region at least one monolithically integrated circuit element is formed. In particular, such an active region may form a surface region of a wafer or an electronic component at a front side thereof. However, it is also possible that the active region extends vertically through the entire wafer or electronic component.

In the context of the present application, the term “breaking edge” may particularly denote a rough or poorly defined exterior surface region at a lateral position of an electronic component resulting from a process of mechanically breaking an electronic component from one or more adjacent other electronic components. In particular, such a breaking edge may be arranged at an upper lateral position of the electronic component. It is however also possible that such a breaking edge may be arranged at a lower lateral position of the electronic component. A sidewall portion of the electronic component between an upper lateral position and a lower lateral position thereof may be free of a breaking edge. For example, a breaking edge may laterally protrude beyond said central sidewall portion of the electronic component between the upper lateral position and the lower lateral position. A breaking edge may be characterized by a poorly defined surface topology with random surface profile resulting from a breaking process. Hence, a breaking edge, rough edge or waste edge may correspond to a breaking trajectory or breaking line obtained when singularizing an electronic component from a wafer compound by breaking. Consequently, a breaking edge may have a lower degree of spatial order as compared to an exterior surface of the sidewall lining.

In an embodiment, the method comprises separating the electronic components from each other along the separation trenches. For this purpose, the wafer may be separated along the separation trenches and thus along separation lines extending in rows parallel to each other and in columns parallel to each other and perpendicular to the rows.

In particular, the described separation may be accomplished by one or a combination of the following four options, and/or by taking one or more other measures:

In an embodiment, separating the electronic components comprises arranging the wafer on a (preferably elastically deformable) foil and disrupting the wafer along the separation trenches by expanding the foil. The still integral wafer with its separation trenches may be attached to the foil so that a lateral expansion of the foil may lead to a breakage of the wafer into the individual electronic components along the separation trenches. Such a foil may be a dicing tape.

In an embodiment, separating the electronic components comprises thinning the wafer from a back side opposing a front side in which the trenches are formed. In particular, material of the wafer may be removed from its back side until the bottoms of the separation trenches are reached, which may lead directly to the separation of the wafer into the electronic components at a bottom side. For example, thinning may be accomplished by mechanically grinding, chemical mechanical polishing, etc.

In an embodiment, separating the electronic components comprises removing material of the closing structure. This may separate the electronic components at their top side. For example, a laser beam or a mechanical drill may be guided along the separation trenches for removing material of the closing structure until the void volumes in the separation trenches are opened from a top side. Additionally or alternatively, material of the closing structure may be removed by etching. Removal of material of the closing structure may lead or contribute to a separation of the wafer into separate electronic components.

In an embodiment, separating the electronic components comprises mechanically breaking the wafer along the separation trenches. Upon exerting a breaking force to the wafer, the latter may be broken into individual portions or even electronic components along the mechanically weakest lines, i.e. along the separation trenches with their void volumes. Said breaking may create breaking surfaces on a top side (in particular through material of the closing structure) and/or at a bottom side (in particular through material of the sidewall lining and/or wafer semiconductor material).

In an embodiment, the method comprises forming at least one integrated circuit element in an active region and/or at least one protection trench around an active region of each electronic component, and at least partially simultaneously with said forming of said integrated circuit elements and/or said protection trenches, forming said separation trenches. Such an integrated circuit element may be monolithically integrated into a semiconductor body of the wafer. For example, such an integrated circuit element may comprise a transistor (for instance a field effect transistor or a bipolar transistor), a diode, etc. It is possible that said at least one integrated circuit element is formed exclusively in a surface portion of the semiconductor body on the front side of the wafer, for instance when creating an electronic chip with lateral current flow. However, it is alternatively possible that said at least one integrated circuit element is formed to extend vertically through the entire semiconductor body between the front side and the back side of the wafer, for instance when creating an electronic chip with vertical current flow. The mentioned protection trenches may be deep trench isolation (DTI) trenches for specifically protecting the active region around a circumference thereof. The at least partially simultaneous formation of integrated circuit elements and/or protection trenches on the one hand and the separation trenches on the other hand (for instance by a front end of the line process) renders the manufacturing method particularly efficiently.

In an embodiment, an exterior surface of a lower portion of the sidewall of the electronic component is a further breaking edge. In particular, said further breaking edge at a bottom portion of the sidewall of the electronic component may be the result of a breaking of a (in particular semiconductor) portion of the wafer which has been located below a separation trench prior to the separation process. Additionally or alternatively, said further breaking edge may also comprise a portion of the sidewall lining which has lined a bottom of a separation trench prior to the separation process.

In an embodiment, a roughness (Ra or Rz) at the breaking edge (and/or at the further breaking edge, if present) is different from, in particular is higher than, a roughness of the sidewall lining apart from the breaking edge(s). This lateral roughness profile along the sidewall of the electronic component may be the consequence of a singularization of the electronic components from the wafer by breaking. Such a process of breaking may create at least one breaking edge with random shape or surface profile (rather than with predefined shape or surface profile) so that the roughness of the breaking edge(s) may be different from the roughness of the sidewall lining or a portion thereof which does not participate during the breaking process due to the void volume adjacent thereto. In particular, the roughness at the breaking edge(s) may be an excessively high roughness resulting from the breaking process. An upper breaking edge may be defined by material of the closing structure rather than by material of the sidewall lining. A lower breaking edge may be defined by material of the semiconductor wafer and by material of the sidewall lining. Furthermore, the breaking edge may be largely undefined with a random non-order surface profile. In an embodiment, an exterior surface of the sidewall lining below the upper breaking edge and above the lower breaking edge is not defined by breaking.

In an embodiment, the electronic component comprises a discontinuity, in particular a step and/or a sawtooth structure, in an interface region between the breaking edge and the sidewall lining apart from (in particular below) the breaking edge. Such a discontinuity may be the result of a breakage process along the breaking edge. When shaped as a step, the discontinuity may correspond to a material interface between sidewall lining and a broken portion of a closing structure. Such a step and/or sawtooth structure may be formed as a result of an undefined breakage process. Optionally, a corresponding discontinuity may also be formed between a lower breaking edge (if present) and an unbroken portion of the sidewall lining.

In an embodiment, the sidewall lining comprises an electrically insulating material (for example silicon oxide or silicon nitride). In particular, an electrically insulating sidewall lining may directly cover semiconductor material of the wafer or the electronic component. Consequently, the sidewall lining may electrically decouple a sidewall of the semiconductor material with regard to an environment. This may electrically passivate the electronic component. In particular, an undesired deposition of metallic material directly on the semiconductor material may be reliably prevented when configuring the sidewall lining of an electrically insulating material. Also the closing structure may be formed of an electrically insulating material.

In one embodiment, the sidewall lining and the closing structure form an integral common structure of the same material. Both may be formed by a common process. Alternatively, the sidewall lining and the closing structure may be distinguishable structures of different materials. They may be formed by different processes.

In an embodiment, a vertical thickness of the semiconductor body is not more than 60 μm, in particular is in a range from 5 μm to 60 μm, more particularly is in a range from 10 μm to 60 μm. Hence, the wafer and the electronic component separated therefrom may be ultra-thin devices. With such a configuration, the described separation concept is of utmost advantage, since it enables formation of separation trenches extending almost entirely through the semiconductor substrate.

In an embodiment, the electronic component has a rectangular outline or has an outline with rounded corners. When embodied as rectangle with four sharp corners, substantially no semiconductor material remains between separated electronic components. This may simplify subsequent handling of the separated electronic components. When embodying each respective electronic component as rectangular structure with rounded corners, a risk of breakage in corner regions of the electronic components during singularization along the separation trenches may be strongly suppressed.

In an embodiment, the electronic component is configured as electronic component with vertical current flow. In particular, electric current may flow between a pad on a lower main surface of the electronic component through semiconductor material of the electronic component to another pad at an upper main surface of the electronic component, or vice versa. For instance, the electronic chip experiencing a vertical current flow may be configured as a field effect transistor chip in which a source pad and a gate pad are arranged on one main surface and a drain pad is arranged on the opposing other main surface of the electronic chip. For instance, an electronic component embodied as a vertical device with integrated field effect transistor may have a gate pad and a source pad at a front side (from which also the assigned separation trench extends into the semiconductor body) of the electronic component, whereas a drain pad may be arranged at a back side. Between front side and back side, a channel and drift zone may be located.

In an embodiment, each separation trench surrounds, in particular fully circumferentially surrounds, an assigned electronic component. This allows to separate the respective electronic component along a circumferentially closed separation line defined by the continuous separation trench. Alternatively, it is possible that the separation trench is formed by a plurality of individual trench sections being separated by walls. Descriptively speaking, this may lead to a dashed structure in a top view.

In an embodiment, a vertical thickness of a portion of the closing structure extending into the trench divided by a vertical extension of the trench is in a range from 5% to 30%, in particular from 10% to 20%. On the one hand, this may ensure a reliable closure of the separation trench at a top side thereof, thereby reliably preventing contaminations from entering the separation trench. On the other hand, the mentioned design rule ensures that a pronounced subsection of the vertically extending separation trench remains hollow, which promotes a reliable and low force separation.

In an embodiment, the wafer comprises protection trenches, each protection trench being arranged between an assigned separation trench and an active region of an assigned electronic component. Such an additional protection trench may additionally protect the active region of the electronic component against a mechanical breakout of a breaking trajectory into an active region of an electronic component. The active region of an electronic component may be surrounded by the protection trench, which may be surrounded, in turn, by a separation trench.

In an embodiment, each protection trench is filled (preferably completely) with a protection material. For instance, such a protection material may comprise an electrically insulating material (such as silicon oxide) as a sidewall lining of the protection trenches, wherein a remaining hollow volume of the protection trenches may be filled with a semiconductive or an electrically conductive material (such as polycrystalline silicon or a metal).

In an embodiment, the wafer comprises further protection trenches, each further protection trench being arranged to surround an assigned separation trench. Descriptively speaking, each separation trench may be surrounded both along an interior side as well as along an exterior side by a respective protection trench (which may be filled with protection material, as described above). Surrounding each separation trench by a pair of interior and exterior protection trenches may provide additional protection of the active region of the electronic components during the manufacturing process.

In an embodiment, the array comprises electronic components of at least two different sizes and/or of at least two different outlines. Advantageously, the concept of defining separation lines by separation trenches surrounding each individual electronic component is properly compatible with the formation of electronic components of different dimensions and/or with different exterior shapes. This increases the flexibility of a circuit designer.

In an embodiment, a vertical extension of each separation trench is in a range from 5 μm to 30 μm, in particular is in a range from 10 μm to 20 μm. For instance, the vertical extension of a separation trench divided by a thickness of the electronic component may be in the range from 70% to 100%, in particular in a range from 80% to 95%. For instance, such trenches may be formed easily by etching. Trenches of the mentioned depth may allow a precise separation of the individual electronic components with high yield and high throughput.

In an embodiment, a horizontal width of each separation trench is in a range from 0.5 μm to 4 μm, in particular is in a range from 1 μm to 2 μm. Thus, only a minimum portion of the wafer is sufficient for defining the miniaturized separation trenches. Consequently, silicon material of the wafer may be used highly efficiently.

In an embodiment, a horizontal width of the void volume is below 0.2 μm, in particular is below 0.1 μm. Thus, the mechanical integrity of the wafer may be maintained to a large degree prior to the separation, which stabilizes the wafer mechanically during processing.

In an embodiment, the electronic component is a power semiconductor chip. Such a power semiconductor chip may have integrated therein one or multiple integrated circuit elements such as transistors (for instance field effect transistors like metal oxide semiconductor field effect transistors and/or bipolar transistors such as insulated gate bipolar transistors) and/or diodes. Exemplary applications which can be provided by such integrated circuit elements are switching purposes. For example, such another integrated circuit element of a power semiconductor device may be integrated in a half-bridge or a full bridge. Exemplary applications are automotive, industrial or consumer applications.

The one or more electronic components (in particular semiconductor chips) may comprise at least one of the group consisting of a diode, and a transistor, more particularly an insulated gate bipolar transistor. For instance, the one or more electronic chips may be used as semiconductor chips for power applications for instance in the automotive, industrial or consumer field. In an embodiment, at least one semiconductor chip may comprise a logic IC or a semiconductor chip for RF power applications. In one embodiment, the semiconductor components may be used as one or more sensors or actuators in microelectromechanical systems (MEMS), for example as pressure sensors or acceleration sensors, as a microphone, as a loudspeaker, etc.

As substrate or wafer for the semiconductor components, a semiconductor substrate, i.e. a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

Furthermore, exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALD), sputtering, etc.).

The above and other objects, features and advantages of the present invention will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

A gist of an exemplary embodiment can be seen in the formation of a singulation or separation trench with a void that may be integrated advantageously in a front end of the line (FEOL) process on a chip front side. Such separation trenches may be advantageously used to separate the chips (or other electronic components), for example during a foil expansion process after back side processing of the wafer.

In particular, an exemplary embodiment provides a wafer with singulation trenches having a void delimited at least laterally by a sidewall lining and upwardly by a closing structure. More specifically, such singulation or separation trenches may be formed in a chip front side with an interior void for promoting and defining chip singulation.

According to an exemplary embodiment, a singulation or separation trench may be provided with a void that may be integrated in a FEOL process on the chip front side. After sidewall lining and closure on a top side, the hollow separation trench may be used to separate the electronic components (in particular semiconductor chips), for example during a foil expansion process after back side processing of the wafer.

Advantageously, the singulation trench may be partially filled with a material (for example silicon nitride or silicon oxide or combinations thereof) that is deposited preferably in a non-conformal way, so that a big void is generated in this separation trench. This void may induce a desired mechanical instability which systematically cracks during force exertion during separation, for example during foil expansion. Advantageously, a risk to generate cracks earlier in the process (for example during thinning) may be strongly reduced by an appropriate design of the separation trenches in terms of dimensioning, shaping and material selection, as described herein.

Exemplary embodiments thus enable the formation of a separation trench integrated together with a process of forming a deep trench isolation (DTI) trench, for example when manufacturing field effect transistor-type electronic components on wafer level. Descriptively speaking, a DTI trench may divide or partition an electronic component into separate segments. Such a concept may synergistically combine formation of different kinds of trenches simultaneously which may lead to a fast and simple processing.

Moreover, covering sidewalls of the separation trenches by a sidewall lining and closing a top side of the separation trenches with a closing structure maintaining an interior void volume may prevent thick power metal from covering the trench both on the front side and on the back side of the chip-type electronic components. Simultaneously, the maintenance of a void volume in the separation trenches may ensure a low force separation of the electronic components.

After separation of the electronic components using the separation trenches as mechanical weak points defining separation lines (for instance by, but not limited to, foil expansion), the separated electronic components (in particular chips) may be mounted on a separate foil with larger die to die distance in order to prevent die knocking after pick up.

Advantageously, exemplary embodiments may reduce a space for dicing to a very small value of for example less than 50 μm, in particular less than 10 μm, for example 2 μm. This may lead to a highly efficient manufacturing process and a high yield. In particular, very small trench widths may be made possible. Furthermore, metal (for example copper) spacing on the back side of the electronic components may be strongly limited. In this context, a pattern plating process may be beneficial. Advantageously, filling material in each separation trench may act as a sidewall protection and may prevent an undesired silicon reaction with metals and/or humidity. Furthermore, exemplary embodiments may enable a high degree of flexibility in the layout, in particular in terms of shape and dimensions of the electronic components. Contrary to conventional approaches, not only straight cut lines may be implemented. By correspondingly designing the formed separation trenches, the layout can also deviate from straight lines. For example, edge rounding may be possible in order to stabilize thin chips at the corners. Moreover, it may also be possible to use several parallel separation trenches. Advantageously, also different chip sizes can be implemented in a common wafer.

Further advantageously, chip breaking strength may be higher than for conventional laser or mechanical dicing when implementing the concept of separation trenches. Further advantageously, there is no risk of damage or defects from trench etching (in particular no chipping, pre-damage, peeling, as may occur in conventional approaches).

Further advantageously, the effort in terms of chip separation when implementing separation trenches can be rendered independent of chip size, since the process time does not significantly vary with open area of trench etch in this range. Hence, exemplary embodiments may reduce the manufacturing effort while simultaneously increasing yield and quality.

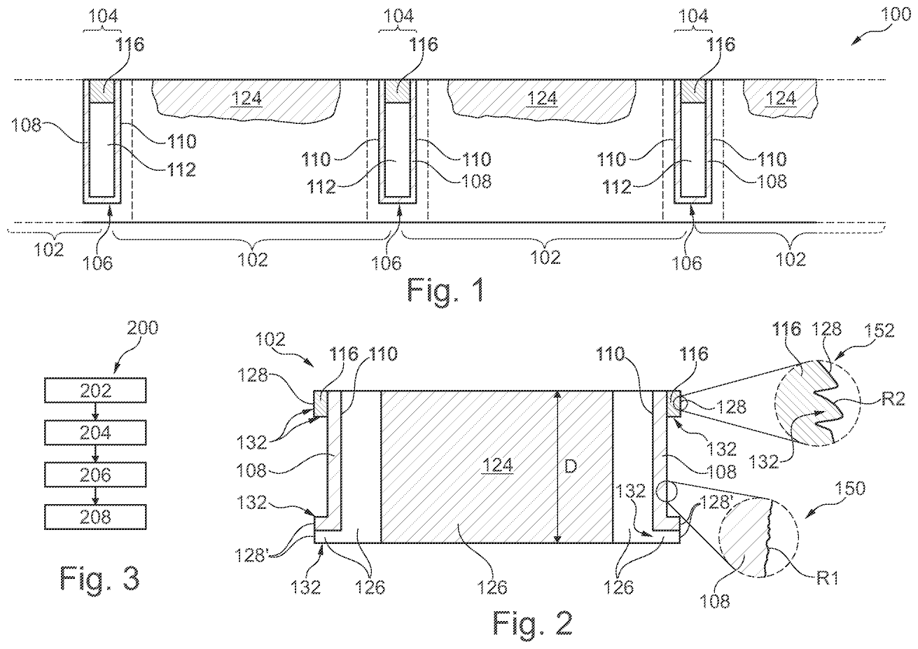

FIG. 1 shows a cross-sectional view of a wafer 100 according to an exemplary embodiment.

As shown in FIG. 1, the illustrated wafer 100 comprises an array of a plurality of electronic components 102, wherein a separation frame 104 separates neighboured electronic components 102. For example, each of the electronic components 102 may comprise an active region 124 in a central upper portion thereof. Moreover, separation trenches 106 are formed in the separation frame 104 between adjacent electronic components 102. Furthermore, a sidewall lining 108 lines sidewalls 110 of the separation trenches 106 for partially filling the separation trenches 106 while maintaining a void volume 112 therein. Apart from this, a closing structure 116 is provided for closing an exterior opening 114 of the separation trenches 106 while maintaining the void volume 112 therein.

FIG. 2 shows a cross-sectional view of an electronic component 102, for instance embodied as semiconductor chip, according to an exemplary embodiment.

The illustrated electronic component 102 comprises a semiconductor body 126 (for instance a silicon substrate), and an active region 124 in and on a central portion of the semiconductor body 126. Furthermore, a sidewall lining 108 covers a sidewall 110 of the semiconductor body 126. The sidewall lining 108 comprises another material (for example a dielectric material) than the semiconductor body 126. Beyond this, an exterior surface of an upper portion of a sidewall of the electronic component 102 is a breaking edge 128. In the illustrated embodiment, the breaking edge 128 is defined by an exterior surface of a residue of a closing structure 116, as shown in and described above referring to FIG. 1.

As indicated by a detail 150, an exposed sidewall of the sidewall lining 108 of the electronic component 102 may have a roughness R1 (for instance in terms of Ra or Rz) being different from a roughness R2 (for instance in terms of Ra or Rz) of an exposed surface of the residue of the closing structure 106, as indicated by another detail 152. Depending on the separation process, the condition R2>R1 may be met (as shown), or the condition R2<R1 (not shown).

Optionally, an exterior surface of a lower portion of the sidewall of the electronic component 102 may be a further breaking edge 128′. Such a further breaking edge 128′ at a bottom portion of the sidewall of the electronic component 102 may be the result of a breaking of a semiconductor portion of the wafer 100 which has been located below a separation trench 106 prior to the separation. Said further breaking edge 128′ may also comprise a portion of the sidewall lining 108, which has lined a bottom of a separation trench 106 prior to the separation. The above mentioned roughness R1 may be different from (for instance may be smaller than) a roughness (for instance in terms of Ra or Rz) of the exposed surface of the further breaking edge 128′.

Optionally, one or more discontinuities 132 may be formed along the vertical sidewall of the electronic component 102, in particular in the region of the breaking edge 128 and/or of the further breaking edge 128′. In the shown embodiment, the discontinuities 132 are embodied as locally restricted lateral protrusions protruding beyond a vertically central unbroken sidewall of the sidewall lining 108.

The electronic component 102 may have a very small vertical thickness, D, for instance 60 μm or less, or even 20 μm or less.

FIG. 3 shows a flowchart of a method of processing a wafer 100 according to an exemplary embodiment. For the description of FIG. 3, reference signs according to FIG. 1 and FIG. 2 will be used.

As indicated by a block 202, the method comprises providing the wafer 100 with a separation frame 104 separating neighboured electronic components 102.

As indicated by a block 204, the method comprises forming separation trenches 106 in the separation frame 104.

As indicated by a block 206, the method comprises at least partially lining sidewalls 110 of the separation trenches 106 with a sidewall lining 108 for partially filling the separation trenches 106 while maintaining a void volume 112 therein.

As indicated by a block 208, the method comprises closing an exterior opening 114 of the separation trenches 106 by a closing structure 116.

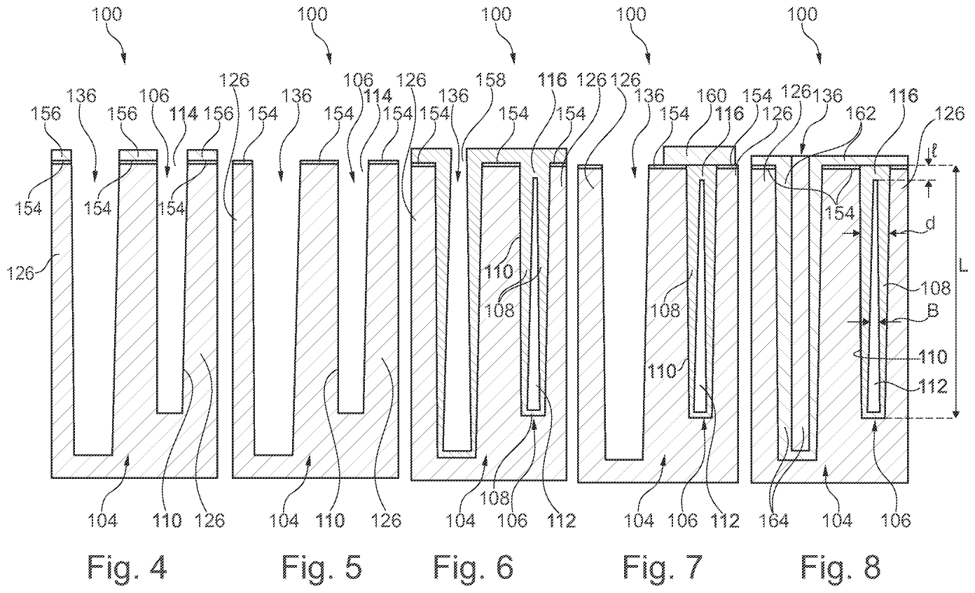

FIG. 4 to FIG. 11 show cross-sectional views of structures obtained during carrying out a method of separating a wafer 100 (only part of which being shown in FIG. 4 to FIG. 11) into electronic components 102 (only two of which being shown partially in FIG. 4 to FIG. 11) according to an exemplary embodiment. For instance, a wafer 100 may have a diameter in a range from 150 μm to 450 μm, in particular from 200 mm to 300 mm. The number of electronic components 102 separated from a wafer 100 may be at least 10, in particular at least 100, more particularly at least 200. For instance, wafer 100 may be a silicon wafer. Although not shown in FIG. 4 to FIG. 11, a further carrier may be optionally provided above wafer 100, for instance for stabilizing purposes. The structures illustrated in FIG. 4 to FIG. 11 focus on a processing of the wafer 100 in a separation frame 104 separating neighboured electronic components 102 (see FIG. 11) from each other.

Referring to FIG. 4, separation trenches 106 are formed as vertical recesses in the separation frame 104. Preferably, each separation trench 106 is formed as a circumferentially closed recess arranged around one or more integrated circuit elements in an active region (see reference sign 124 in FIG. 1 and FIG. 2) of each electronic component 102 (not shown in FIG. 4).

For example, the separation trenches 106 may be formed by etching. Depending on the etching process used, the separation trenches 106 may have vertical sidewalls 110 or may have tapering sidewalls 110. For defining the regions of the semiconductor material of the wafer 100 to be etched, the exterior surface on the front side of the wafer 100 may be covered with a patterned structure, here embodied by a double layer 154, 156. For example, layer 154 may be a silicon nitride or silicon oxide layer or a layer made of another appropriate material, whereas layer 156 may be silicon oxide or a photoresist.

Simultaneously with the formation of the separation trenches 106, protection trenches 136 may be formed. For instance, the protection trenches 136 may be embodied as deep trench isolation (DTI) trenches. Additionally or alternatively, it is possible that at least part of an integrated circuit element of active region 124 is formed simultaneously with the separation trenches 106 (not shown). In particular, the separation trenches 106 may be formed during a front end of the line (FEOL) process. Hence, FIG. 4 illustrates simultaneous integration of DTI and singulation trenches. The singulation or separation trenches 106 may later promote separation of the individual electronic components 102, whereas the protection trenches 136 may protect an active region 124 of a respective electronic component 102 from mechanical outbreak during separation of the electronic components 102.

As shown in FIG. 4 as well, the vertical extension of the protection trench 136 may be larger than the vertical extension of the separation trench 106. Furthermore, the horizontal extension of the protection trench 136 may be larger than the horizontal extension of the separation trench 106.

Referring to FIG. 5, patterned layer 156 may be removed, for instance by an oxide wet etch or by stripping photoresist material.

Referring to FIG. 6, the previously exposed sidewalls 110 of the separation trenches 106 and of the protection trenches 136 may be coated with a sidewall lining 108. Consequently, the separation trenches 106 and the protection trenches 136 are partially filled with the sidewall lining 108 while maintaining a void volume 112 therein. By the described coating process, it may also be possible to close an exterior opening 114 of the separation trenches 106 by a closing structure 116. In contrast to this, an exterior opening 158 of the protection trenches 136 may remain accessible from an exterior side of the wafer 100.

In the described embodiment, the sidewall lining 108 and the closing structure 116 are formed simultaneously by an integral material. For instance, the sidewall lining 108 and the closing structure 116 may be formed by silicon oxide deposition (for instance in a non-conformal manner). Advantageously, both the sidewall lining 108 and the closing structure 116 are made of an electrically insulating material covering semiconductive material of wafer 100 to thereby protect the latter against undesired coverage by metal, dirt or dust, or from any other contamination. The closing structure 116 may also contribute to the protection of the separation trenches 106 against entry of contaminants.

Alternatively, the closing structure 116 may comprise another material than the sidewall lining 108 (not shown). This may allow to individually adjust the functions of the closing structure 116 and of the sidewall lining 108.

Depending on the process of applying sidewall lining 108, the thickness of the sidewall lining 108 in separation trenches 106 may be constant or may vary in a vertical direction. For instance, said thickness may taper downwardly.

In order to obtain the structure shown in FIG. 7, the structure shown in FIG. 6 is subjected to a material removal process removing excessive dielectric material above layer 154. For example, layer 154 may function as a stop layer for the material removal process. The material removal may be embodied as chemical mechanical polishing (CMP), plasma etching, mechanically grinding, etc.

Thereafter, a photoresist 160 may be applied (for instance a lithographically negative photoresist), and may be patterned by lithography so as to cover only the separation trenches 106 and a region surrounding the latter, but not the protection trenches 136. Thereafter, the sidewall lining 108 may be removed from the protection trenches 136, for instance by etching (in particular by wet etching).

The photoresist 160 may then be removed, for instance by stripping.

Referring to FIG. 8, further electrically insulating material 162 may be applied into the protection trenches 136 and on the front side of the wafer 100. For example, the further electrically insulating material 162 may be silicon oxide formed using TEOS (tetraethyl orthosilicate) as silicon source. Remaining void volume in the protection trenches 136 may then be filled with a semiconductive or an electrically conductive material, such as polycrystalline silicon. Thereafter, the surface may be planarized by a material removal process, for instance CMP, plasma etching or mechanically grinding.

FIG. 8 shows several dimensions relating to the separation trenches 106: A vertical thickness 1 of a portion of the closing structure 116 extending into the separation trench 106 divided by a vertical extension L of the separation trench 106 may be preferably in a range from 10% to 20%. The vertical extension L of each separation trench 106 may be preferably in a range from 10 μm to 20 μm. A vertical thickness D of the semiconductor body 126 may be slightly larger than the vertical extension L of each separation trench 106, for instance may be in a range from 10 μm to 60 μm. Furthermore, a horizontal width d of each separation trench 106 may be preferably in a range from 1 μm to 2 μm. A horizontal width B of the void volume 112 may be preferably below 0.1 μm, for instance may be 0.05 μm.

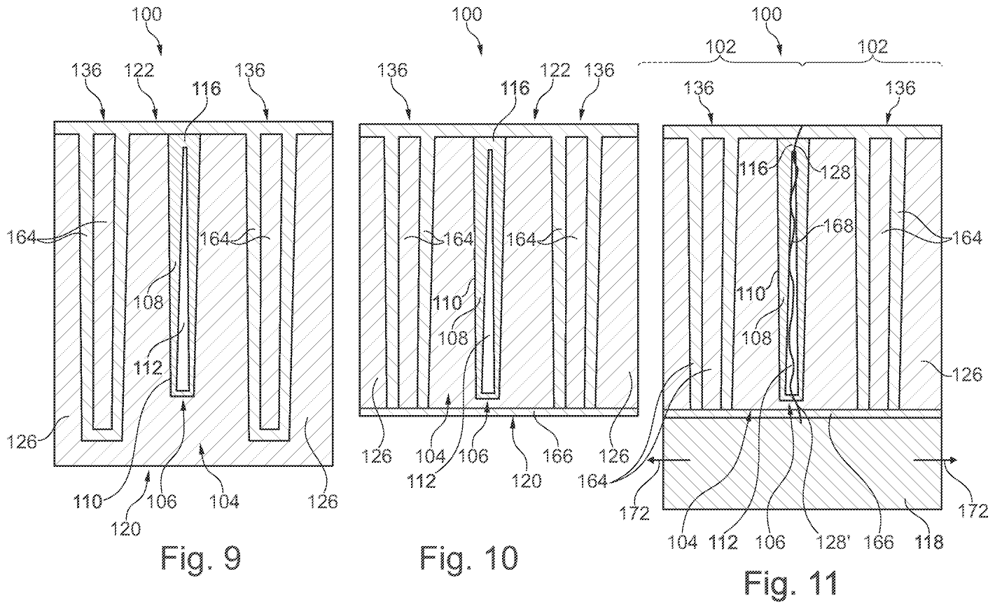

FIG. 9 to FIG. 11, which will be explained in the following, are based on the structure shown in FIG. 8, and show additionally another protection trench 136.

Referring to FIG. 9, the wafer 100 may be further processed from its front side, which is denoted with reference sign 122. For instance, a field effect transistor and/or another circuit element may be integrated in the active region 124 of each electronic component 102 to be separated from wafer 100. Said front side processing may include further processes such as power front side metal formation, etc. As shown with reference sign 162, the separation trenches 106 may be covered on top with interlayer dielectric (ILD), but not with power metal.

Referring to FIG. 10, the wafer 100 may then be subjected to back side processing. The back side is indicated with reference sign 120.

Said back side processing may include removing material from the back side 120 of the wafer 100 until the protection trenches 136 are reached or exposed. This causes a thinning of the wafer 100 from the back side 120 opposing the front side 122 into which the separation trenches 106 are formed. Said thinning is in preparation of a subsequent separation of the wafer 100 into individual electronic components 102, as explained referring to FIG. 11. This material removal may be accomplished for example by polishing the back side 120 into the DTI trenches (i.e. into the protection trenches 136). However, the material removal may stop early enough to not expose the separation trenches 106, as shown as well in FIG. 10. Thereafter, a further electrically insulating layer 166 may be deposited on the back side 120 of the thinned wafer 100, for instance by silicon oxide deposition.

It is also possible to carry out a back side metal deposition and structuring process. As shown, the back side of the wafer 100 in the area of the separation trenches 106 may be covered by a dielectric material, but not with power metal

As shown in FIG. 11, the wafer 100 processed as shown in FIG. 10 may then be separated into individual electronic components 102, wherein the separation process is carried out along the separation trenches 106. As shown, the wafer 100 is arranged on a foil 118 (such as a dicing tape). Thereafter, the wafer 100 is disrupted along the separation trenches 106 by exerting a lateral force (see arrows 172) to thereby expand the foil 118 and break the wafer 100 into individual electronic components 102. In particular, it may be possible to laminate the wafer 100 on the foil 118 before separating the chip-type electronic components 102 via foil expansion. The disruption tears the electronic components 102 apart and separates the wafer 100 into individual electronic components 102 along a separation line 168. Consequently, a crack may be created during foil expansion. In the region of the closing structure 116 a rough breaking edge 128 is created. Depending on the amount of thinning from the back side 120 according to FIG. 10, it is also possible that a further breaking edge 128′ is formed at a bottom side of each separated electronic component 102.

Due to the separating by breaking, a roughness at the top-sided breaking edge 128 (and at the bottom-sided breaking edge 128′, if present) is different from a roughness of the unbroken sidewall lining 108 below the breaking edge 128 (and above the further breaking at 128′), see details 150, 152 and discontinuities 132 in FIG. 2.

As shown in FIG. 11, each of the protection trenches 136 may be arranged between an assigned separation trench 106 and an assigned electronic component 102 for protecting an active region 124 of a respective electronic component 102 against a mechanical outbreak during singularization by breaking. As shown, each protection trench 136 is filled completely with a protection material 164. The protection material 164 can be formed by a dielectric sidewall lining and a filling of the remaining void volume with a semiconductor material or a metal, for instance polycrystalline silicon.

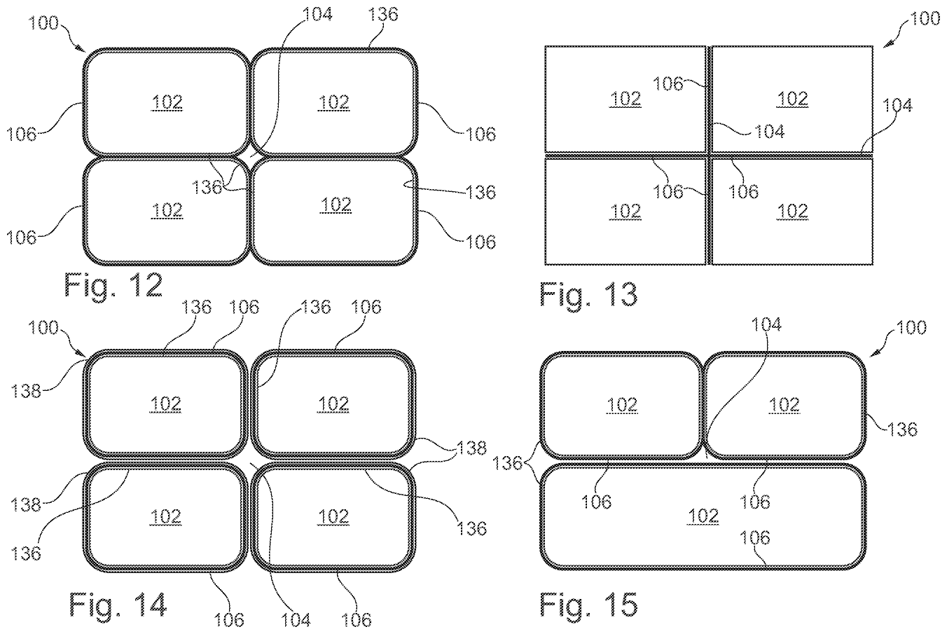

FIG. 12 to FIG. 15 show plan views of wafers 100 according to exemplary embodiments.

Referring to FIG. 12, an embodiment is shown in which each separation trench 106 surrounds fully circumferentially an assigned electronic component 102 with an outline having rounded corners. This avoids a risk of breakage of the electronic components 102 in corner regions during separation. Protection trenches 136 inside of the separation trenches 106 are shown as well.

Referring to FIG. 13, an embodiment is shown in which each separation trench 106 surrounds fully circumferentially an assigned electronic component 102 with a rectangular outline having sharp corners. This may prevent undesired islands of unconnected semiconductor material between separated electronic components 102. This may simplify handling of the separated electronic components 102.

Referring to FIG. 14, an embodiment is shown which, in addition to the embodiment of FIG. 12, comprises further protection trenches 138, wherein each further protection trench 138 being arranged to surround an assigned separation trench 106. Hence, a separation trench 106 may surround an inner protection trench 136 and may be surrounded by an outer further protection trench 138. The further protection trenches 138 may be formed as the protection trenches 136, compare for example FIG. 8. The provision of further protection trenches 138 additionally protects the electronic components 102 and the active region 124 from damage during separation.

Referring to FIG. 15, a wafer 100 is shown which comprises electronic components 102 of different sizes and proportions. This flexibility is made possible by the described separation concept using separation trenches 136.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of processing a wafer, wherein the method comprises:
providing the wafer with a separation frame separating neighboured electronic components;
forming separation trenches in the separation frame;
at least partially lining sidewalls of the separation trenches with a sidewall lining for partially filling the separation trenches while maintaining a void volume therein; and
closing an exterior opening of the separation trenches by a closing structure.

2. The method according to claim 1, wherein the method comprises separating the electronic components from each other along the separation trenches.

3. The method according to claim 2, wherein separating the electronic components comprises at least one of the following features:
arranging the wafer on a foil and disrupting the wafer along the separation trenches by expanding the foil;
thinning the wafer from a back side opposing a front side in which the separation trenches are formed;
removing material of the closing structure;
breaking the wafer along the separation trenches.

4. The method according to claim 1, wherein the method comprises:
forming at least one integrated circuit element in an active region and at least one protection trench around an active region of each electronic component; and
at least partially simultaneously with said forming of said integrated circuit elements and said protection trenches, forming said separation trenches.

5. An electronic component, which comprises:
a semiconductor body;
an active region in and on a central portion of the semiconductor body; and
a sidewall lining covering at least part of a sidewall of the semiconductor body;
wherein the sidewall lining comprises another material than the semiconductor body; and
wherein an exterior surface of at least an upper portion of a sidewall of the electronic component is a breaking edge.

6. The electronic component according to claim 5, wherein a roughness at the breaking edge is different from, in particular is higher than, a roughness of the sidewall lining apart from the breaking edge.

7. The electronic component according to claim 5, comprising a discontinuity, in particular a step or a sawtooth structure, in an interface region between the breaking edge and the sidewall lining apart from the breaking edge.

8. The electronic component according to claim 5, wherein the sidewall lining comprises an electrically insulating material.

9. The electronic component according to claim 5, wherein a vertical thickness of the semiconductor body is in a range from 10 μm to 60 μm.

10. The electronic component according to claim 5, having a rectangular outline with sharp corners or having an outline with rounded corners.

11. The electronic component according to claim 5, configured as electronic component with vertical current flow.

12. The electronic component according to claim 5, wherein an exterior surface of a lower portion of the sidewall of the electronic component is a further breaking edge.

13. A wafer, which comprises:
an array of a plurality of electronic components;
a separation frame separating neighboured electronic components;
separation trenches in the separation frame;
a sidewall lining at least partially lining sidewalls of the separation trenches for partially filling the separation trenches while maintaining a void volume therein; and
a closing structure closing an exterior opening of the separation trenches.

14. The wafer according to claim 13, wherein each separation trench surrounds, in particular fully circumferentially surrounds, an assigned electronic component.

15. The wafer according to claim 13, wherein a vertical thickness of the closing structure or a portion thereof extending into the separation trench divided by a vertical extension of the entire separation trench is in a range from 5% to 30%.

16. The wafer according to claim 13, comprising protection trenches, each protection trench being arranged between an assigned separation trench and an active region of an assigned electronic component.

17. The wafer according to claim 16, wherein each protection trench is filled partially or completely with a protection material.

18. The wafer according to claim 16, comprising further protection trenches, each further protection trench being arranged to surround an assigned separation trench.

19. The wafer according to claim 13, wherein the array comprises electronic components of at least two different sizes and/or of at least two different outlines.

20. The wafer according to claim 13, comprising at least one of the following features:
wherein at least one of the sidewall lining and the closing structure comprises an electrically insulating material;
wherein a vertical extension of each separation trench is in a range from 5 μm to 30 μm;
wherein a horizontal width of each separation trench is in a range from 0.5 μm to 4 wherein a horizontal width of the void volume is below 0.2 μm.
